(19) United States
(12) Patent Application Publication
(10) Pub. No.: US 2003/0020552 A1
(43) Pub. Date: Jan. 30, 2003

(54) Extended range frequency synthesiser

(76) Inventors: Vincent J. Troy, Limerick (IE); Michael P. Daly, Newtownmountkennedy (IE); Brian S. Carroll, Mullingar (IE); Martin Gerard Cotter, Ennis (IE)

Correspondence Address: Iandiorio & Teska, 260 Bear Hill Road, Waltham, MA, 02451-1018, US

(21) Appl. No.: 10/156,612

(22) Filed: May 28, 2002

Related U.S. Application Data
(60) Provisional application No. 60/297,288, filed on Jun. 11, 2001.

(51) Int. Cl. H03L 7/00

(52) U.S. Cl. 331/34

(57) ABSTRACT

An extended range of frequency synthesiser responsive to a number of different input frequencies to provide multiples of those input frequencies as its final outputs includes a phase locked loop having an output frequency range containing a multiple of each of the final output frequencies; and a pre-divider circuit for dividing the input frequencies by a first predetermined number before submission to said phase locked loop and a post divider circuit for dividing the phase locked loop output by a second predetermined number to obtain the final output while operating the phase locked loop in the output frequency range.

### RELATED APPLICATIONS

This application claims priority of U.S. Provisional Application No. 60/297,288, filed on Jun. 11, 2001, and entitled “A FREQUENCY SYNTHESISER, AND A METHOD FOR SYNTHESISING RESPECTIVE OUTPUT FREQUENCY SIGNALS FROM CORRESPONDING INPUT FREQUENCY SIGNALS IN A PHASE-LOCKED LOOP FREQUENCY SYNTHESISER.”

### FIELD OF THE INVENTION

This invention relates to an extended range frequency synthesiser responsive to a number of different frequencies to provide multiples of those input frequencies as its final output.

### BACKGROUND OF THE INVENTION

Phase locked loop (PLL) circuits are used in a number of applications including, for example, supplying faster clock signals to DAC's and ADC's used in conjunction with signal processing circuits on video chips. These PLL's typically receive the incoming clock signal and multiply it by some factor, typically an integer to obtain a faster clock signal. In conventional systems the voltage controlled oscillator (VCO) in the PLL operates right at the desired final output frequency. These circuits are satisfactory in many applications. But in some cases where there are a number of different frequency input clock signals which are multiplied each by a different number, the frequency of the output signals can vary widely. This introduces a number of problems because the PLL includes a loop filter and a voltage controlled oscillator (VCO). A wide ranging input frequency means that the loop filter will be good for some frequencies in the range but not for others and the loop filter is typically an off-chip component not easily adjusted or switched in and out. Further the demand for a wide range of PLL output frequencies can not be met by a VCO which practically speaking has a limited range of oscillator frequencies. Attempts to increase the VCO frequency range makes it more susceptible to noise at its input.

### SUMMARY OF THE INVENTION

It is therefore a primary object of this invention to provide an improved, extended range frequency synthesiser responsive to a number of different input frequencies to provide multiples of those input frequencies at its final output.

It is a further object of this invention to provide such an improved synthesiser which operates within a narrow frequency range and reduces VCO susceptibility to input noise;

It is a further object of this invention to provide such an improved synthesiser which tailors the input frequency to the PLL to the bandwidth of the loop filter.

It is a further object of this invention to provide such an improved synthesiser in which the output of the PLL VCO is a multiple of the desired final output signals and is large enough so that each of the PLL output signals is but a small fractional deviation from the operating frequency so that the loop filter and VCO function within the appropriate frequency range.

The invention results from the realisation that a more effective frequency synthesiser with extended input and output frequency ranges can be achieved by operating the PLL VCO in a frequency range that contains a multiple of the final output signal and is large enough so that each PLL output signal is but a small, fractional deviation from the operating point of the VCO within the frequency range so that the VCO can be optimally operated in a narrow range; and the further realisation that by conforming the input frequencies to a narrow range a number of different frequency inputs can be accommodated by the bandwidth of the loop filter, and the further realisation that these objectives can be accomplished by the use of a pre-divider and post-divider at the input and output of the PLL which can be easily implemented using simple digital circuits e.g. counters.

This invention features an extended range frequency synthesiser responsive to a number of different input frequencies to provide multiples of those input frequencies as its final outputs including, a phase locked loop having an output frequency range containing a multiple of each of the final output frequencies. A pre-divider circuit divides the input frequencies by a first predetermined number before submission to the phase locked loop and a post divider circuit divides the phase locked loop output by a second predetermined number to obtain the final output while operating the phase locked loop in the output frequency range.

In preferred embodiment the phase locked loop may include a voltage controlled oscillator for providing an output which is a multiple of the input to the phase locked loop; a loop divider for dividing the voltage controlled oscillator output by a third predetermined number; a phase detector responsive to the input to the phase locked loop and to the loop divider output for detecting any error between them; and a loop filter responsive to an error detected by the phase detector to drive the voltage controlled oscillator to correct the error. The first and second predetermined numbers may be integers. The third predetermined number may be an integer. The first, second and third predetermined numbers may be different. The phase locked loop may have an operating point within the frequency range and the multiples of the final output frequencies may deviate only fractionally from the operating point.

### BRIEF DESCRIPTION OF THE DRAWINGS

Other objects, features and advantages will occur to those skilled in the art from the following description of a preferred embodiment and the accompanying drawings, in which:

FIG. 1 is a block diagram of an extended range frequency synthesiser according to the invention; and

FIG. 2 is more detailed schematic diagram of the synthesiser of FIG. 1.

### PREFERRED EMBODIMENT

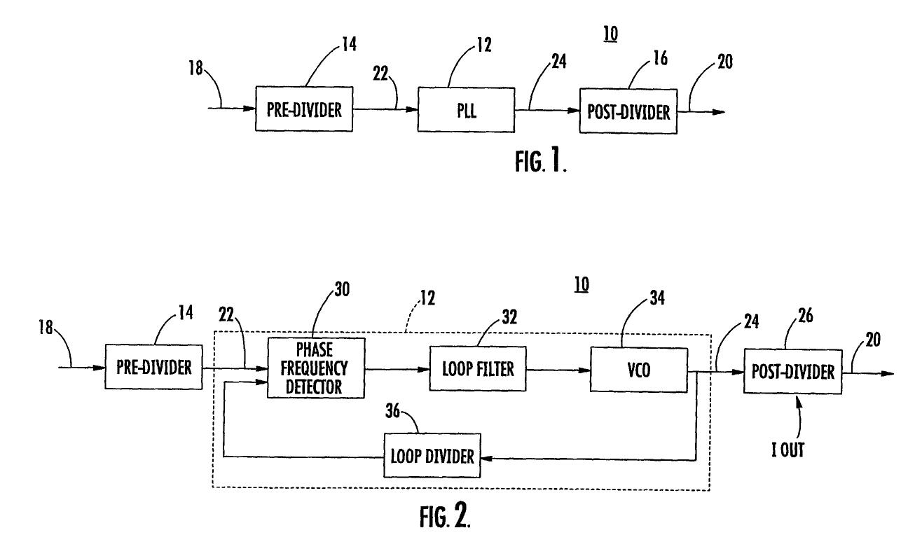

There is shown in FIG. 1 an extended range frequency synthesiser 10 according to this invention including a phase locked loop circuit 12 which may be made in the conventional manner but having at its input a pre-divider 14 and at its output a post-divider 16 which may be simple counter circuits easily implemented in integrated circuit technology. The purpose of this circuit is to take an input signal such as a clock signal at input 18 and multiply it using phase locked loop circuit (PLL) 12 to provide a faster final output signal at the output 20 which is a multiple of the clock signal at input 18. These faster clock signals can be used to drive the ADC's and the DAC's that service the signal processing portion of a video chip as explained in the Background, supra. Thus the input the frequencies presented to the phase locked loop circuit 12 are within the range of the loop filter; and the VCO output though accommodating a wide range of final outputs at 20 need produce only a more limited band of frequencies within the range of VCO 34. The pre-divider 14 divides the input by some number typically but not necessarily a whole number or integer so that the frequencies delivered at the input 22 of phase locked loop circuit 12 are always within the range of the loop filter while the post-divider 16 ensures that the output 24 from phase locked loop 12 is divided down to give an intended multiple at output 20 of input 18.

Phase locked loop 12 typically includes phase frequency detector 30, FIG. 2, loop filter 32, voltage controlled oscillator 34, and the loop divider 36. In operation voltage controlled oscillator 34 provides an output 24 to the post divider 26 and to loop divider 36. Loop divider 36 divides the output signal 24 from VCO 34 by some number typically but not necessarily an integer. For example, if it is desired to have phase locked loop 12 multiply the input 25 signal by the number 4, loop divider 36 will divide the output 24 of VCO by a factor of 4. The output from loop divider 36 is submitted to phase detector 30 along with the input signal on line 22. Any difference between the two signals is detected and delivered to loop filter 32 which averages or integrates that signal and provides a voltage to voltage control oscillator 34 to drive it either up or down in frequency until the output from loop divider 36 matches that at input 22 to phase detector 30. In this way the input is multiplied by the selected number and provides a clock signal at the output which is a multiple of the clock signal at the input.

This phase locked loop approach works well except when there are a number of different frequency inputs that must be serviced and a number of different multiples that must be applied to them by the loop divider 36. When a wide range of final output frequencies is desired the voltage controlled oscillator cannot practically service the entire range to provide the necessary multiple of the input at the output. In addition, when the input varies over a wide range of frequencies loop filter 32 will not have the correct bandwidth to properly filter all the different input frequencies.

To overcome this problem this invention uses a pre-divider 14 and post-divider 16. Pre-divider 14 multiplies the input signal 18 by a number, typically a whole number or integer such as 1, 2, 3 . . . , in order to deliver on line 22 to phase detector 30 the signal conforming to the bandwidth of loop filter 32. Post divider 16 divides the output from VCO 34. In accordance with this invention, VCO 34 is made to provide an output at 24 which is a multiple of the final output desired at 20. Post-divider 26 simply divides down the frequency of the VCO output to obtain the desired multiple of final output 20. This is explained with respect to Table I.

TABLE I

| Video | Input | Pre- | Loop | PLL i/p | VCO | Post- | Output |
|---|---|---|---|---|---|---|---|
| Format | Frequency | divide | divider | frequency | frequency | divide | frequency |
| SD/PS | 27 MHz | 1 | 12 | 27 MHz | 324 MHz | 3 | 108 MHz |
| HDTV | 74.25 MHz | 3 | 12 | 24.75 MHz | 297 MHz | 2 | 148.5 MHz |

Thus as shown in Table I, the extended range frequency synthesiser can easily handle two widely differing frequency inputs and produce two widely varying outputs while loop filter 32 and VCO 34 in phase locked loop 12 are operating wholly within their operating ranges. Referring to Table I, and assuming a video format SD/PS with a desired input frequency at 18 of 27 MHz and a desired final output frequency at 20 of 108 MHz (4×27 MHz=108 MHz) the pre-divider circuit 14 divides the input frequency 27 MHz at input 18 by a number 1. Thus the input at 22 to phase detector 30 in phase locked loop 12 is still 27 MHz. However loop divider 36 now divides the output of VCO 34 by the number 12 so the input of VCO 34 is 324 MHz. This is three times the desired final output 20 of 108 MHz. Thus post-divider divides the 324 MHz output 24 from VCO 34 by the number 3 to obtain the 108 MHz final output at 20. Referring again to Table I, and assuming a video format HDTV, the input frequency will be 74.25 MHz. Supposing now that the final output frequency 20 is desired to be 148.5 MHz: the pre-divider circuit 14 will divide the input 18 of 74.24 MHz by the number 3 to obtain the input 22 to the phase locked loop of 24.75 MHz. Loop divider 36 divides the output of VCO by the number 12 so that the output of VCO 34 produces a frequency of 297 MHz. This is just twice the desired final output 20 of 148.5 MHz and so post-divider 16 divides the output of VCO by two so that the 297 MHz is transformed to the desired 148.5 MHz final output at 20.

Looking again at Table I, it can be seen that while the two inputs of 27 MHz and 74.25 MHz differ by a factor of 3:1 at input 18, when they are submitted to phase locked loop 12 at input 22 they differ by a much smaller amount specifically 2.25 MHz or 8.33%. Thus loop filter 32 can easily be made to service both inputs properly within its bandwidth. Similarly, while the output frequencies are roughly in a ratio 3:2 or a 50% difference, VCO 34 faces no such disparity for it need only produce outputs of 324 MHz and 297 MHz which are barely a 10% variation.

Thus by choosing an output for VCO 34 which is a multiple of all the outputs desired at final output 20, VCO 34 can be made to operate within an appropriate narrow frequency range while the frequencies at final output 20 can differ greatly. Ideally the output at VCO 34 will be high so that even though there are substantial variations in the output frequency, the effective variation can be but a fraction of the nominal VCO frequency so there is only a small variation percentage wise. While only two examples are shown in Table I any number of different input frequencies and output frequencies can be accommodated by choosing the proper VCO frequency and then applying the pre-divider and post-divider numbers accordingly.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments.

Other embodiments will occur to those skilled in the art and are within the following claims:

What is claimed is:

1. An extended range frequency synthesiser responsive to a number of different input frequencies to provide multiples of those input frequencies as its final outputs comprising:
a phase locked loop having an output frequency range containing a multiple of each of the final output frequencies; and
a pre-divider circuit for dividing the input frequencies by a first predetermined number before submission to said phase locked loop and a post-divider circuit for dividing the phase locked loop output by a second predetermined number to obtain the final output while operating the phase locked loop in said output frequency range.

2. The extended range frequency synthesiser of claim 1 in which said phase locked loop includes a voltage controlled oscillator for providing an output which is a multiple of the input to the phase locked loop; a loop divider for dividing the voltage controlled oscillator output by a third predetermined number; a phase detector responsive to the input to the phase locked loop and to the loop divider output for detecting any error between the two, and a loop filter responsive to an error detected by said phase detector to drive the voltage controlled oscillator to correct the error.

3. The extended range frequency synthesiser of claim 1 in which the first and second predetermined numbers may be integers.

4. The extended range frequency synthesiser of claim 2 in which the third predetermined number may be an integer.

5. The extended range frequency synthesiser of claim 1 in which said phase locked loop has an operating point within said frequency range and said multiples of said final output frequencies deviate fractionally from said operating point.

6. The extended range frequency synthesiser of claim 2 in which said first, second and third predetermined numbers are different.
